(19) United States
(12) Patent Application Publication
(10) Pub. No.: US 2005/0110138 A1
(43) Pub. Date: May 26, 2005

(54) High Speed Electrical On-Chip Interconnects and Method of Manufacturing

(75) Inventor: Achyut Kumar Dutta, Sunnyvale, CA (US)

Correspondence Address: Jeffery J. Brosemer, Ph.D., ESQ., LLC, 138 S. Telegraph Hill Road, Holmdel, NJ, 07733, US

(73) Assignee: BANPIL PHOTONICS, INC., Santa Clara, CA (US)

(21) Appl. No.: 10/904,723

(22) Filed: Nov. 24, 2004

Related U.S. Application Data
(60) Provisional application No. 60/481,703, filed on Nov. 25, 2003.

(51) Int. Cl. H01L 21/00; H01L 23/48; H01L 23/52; H01L 29/40

(52) U.S. Cl. 257/735; 257/776

(57) ABSTRACT

High-speed interconnect systems for connecting two or more electrical elements are provided for on-chip interconnects. The manufacturing process to fabricate the interconnect structure using standard IC process is also provided. The interconnect systems consists of the electrical signal line, inhomogeneous dielectric systems, and with and without ground line, wherein inhomogeneous dielectric system consisting of the opened-trenches into the dielectric substrate or comb-shaped dielectrics to reduce the microwave loss. The signal lines located below and/or above the opened trenches. The opened trenches helps to reduce the microwave-loss induced due to the dielectric material and increases the on-chip interconnects bandwidth. Alternatively, dielectric system can have the structure based on fully electronic or electromagnetic crystal or quasi crystal with the line defect. The interconnect system, can be made in IC for on-chip interconnects using conventional IC manufacturing technology and yet to increase the interconnects-bandwidth.

### CROSS REFERENCE TO RELATED APPLICATIONS

This application claims the benefit of U.S. Provisional Patent Application No. 60/481,703 filed on Nov. 25, 2003.

### FIELD OF THE INVENTION

This invention relates to interconnection of electronics elements in on-chip (inside the chip) interconnection. More particularly, this invention is related to, (a) connecting two or more electronic devices inside a chip by electrical means, useful in high speed chips (processor, memory etc.) for high speed systems including personnel computer (PC) super-computer, game system, imaging system, communication system etc.

### BACKGROUND OF THE INVENTION

Higher levels of integration within electrical integrated circuits (IC) leads to both higher data rates and larger number of IC interconnections. Today, the inherent signal speed of ICs is around 5 GHz, and shortly it will reach 20 GHz and beyond. The number of pin connection has also increased, with single IC requiring close to 2000 interconnection (i.e. single processor), and shortly it will be increased to over 5000. Simultaneously achieving higher data rates and higher interconnect densities for both on-chip and also off-chip, will be increasingly difficult as the IC technologies continue to evolve with increasing signal speed of electronic devices and interconnection number. In on-chip cases (inside the die), as the number of the electronic devices such as transistors are increasing with development of the fabrication technology, the interconnecting of the electronic devices without sacrificing the signal speed is getting challenging. In the on-chip case, high density interconnects, will also be increasingly difficult as the IC technologies continue to evolve with increasing the signal speed and interconnection number.

With increasing of the signal speed and interconnection number within the IC, low-cost high-level interconnect technique compatible to today's manufacturing technology is highly desirable.

Generally, it is known that if the electronic devices (for both on-chip) are connected with the help of the metal conductor (act as the interconnects), electrical signal can be flown and the electronic device can be connected with each other. This is true for low-speed signal, below few MHz. At multi GHz frequencies, interconnect lengths become a significant fraction of the wavelength of the high frequency harmonics, and therefore interconnects must be design with proper concern of attenuation, impedance, and cross talk. Significant attenuation and rise-time degradation can be caused by losses in the transmission line. The transmission line loss is the sum of the conductor loss and dielectric loss, both of which are dependent on the frequency. This dielectric loss is dependent on the loss tangent (dielectric loss) of the materials and it varies from material to material. The less the loss tangent of the dielectric, the lower the transmission loss for the given interconnect distance, fixed signal speed, and fixed conductor loss. Again, signal delay is dependent on the dielectric constant of the material. The lower the dielectric constant, the lower the propagation delays. Therefore, using the low-loss tangent and also low dielectric constant material, would help to increase the signal carrying capacity of the interconnects and also the reduce the propagation delay of the electrical signal flowing through the interconnects.

Today technology development pushes to reduce the size of the electronic device, resulting in utilization of number of the devices inside single chip. As the level of integration targeting for future ‘system-on-a-chip’ design, is increasing, the chip area is also increasing. Novel interconnection technique compatible to standard IC fabrication technology is necessary; yet preserve the signal speed while assuring the adequate isolation for high-speed data communication.

FIG. 1 is the schematic showing part of on-chip interconnections. As shown in FIG. 1, in on-chip interconnection, single substrate 100 comprises with many electronics devices 102, and is connected by the metal conductor 104. Dielectric layer 106 such as silicon oxide for Si device isolates each device. Metal conductor such as Al, Cu, W, WSi etc. is used for connecting on chip devices.

Conventional interconnection technology for on-chip is mainly based on the metal electrode connection. Impedance matching is usually not considered. As the signal passes through conductor situated onto the dielectric, signal experiences attenuation due to the dielectrics. To reduce the signal attenuation, repeater is usually used at certain distance interval. The repeater usually consists of the active and passive circuits, and each repeater consumes significant power. Using thousands of repeaters inside the chip requires significant of the power to drive them. It is estimated that for large chips, this power consumption will be approximately 15 to 20% of total chip power budget. Microstrip line or strip-line transmission layout on the dielectric material, usually used in the off-chip multi-Giga-bits interconnects to maintain the impedance of the transmission line. These kinds of transmission line can be used in on-chip interconnects too. FIG. 2A shows a cross-sectional of a microstrip layout, which refers to a trace routed as the top or bottom layer, for example, of an IC for the case of on-chip interconnection. The electrical conductor 140A with width W and thickness T are laid on the dielectric material 142A having height H. The ground or power line 144A is located opposite of the signal conductor 140A. FIG. 2B is the cross-sectional view of strip line layout, which uses a trace 140B routed on the inside layer 142B for example of a IC and has two voltage-reference planes (i.e. power and/or ground) 144B and 144B′. Both metal conductor, traditionally used in on-chip interconnects and also future transmission line (FIG. 3), will have microwave loss, experienced due to the dielectric materials as signal speed increases.

For high-speed signal interconnection, lower loss tangent (and lower dielectric constant) is necessary. Low loss-tangent and low dielectric constant material offers following functions for on-chip interconnects;
(i) higher density interconnection due to reduction of the cross-talk, (ii) reducing the capacitance of the interconnection, helping to transfer the signal longer distance, (iii) lower propagation delay, and (iv) reducing the microwave loss and help to transmit the longer distance. In other words, help to transmit the higher speed signal to linger distance.

Besides the loss-tangent of the dielectric materials, the microwave loss due to electrode also limits the bandwidth of the interconnection. Microwave-loss occurs due to the electrode structure mainly from skin-depth of the signal. As Cu's skin-depth at 100 GHz is 0.2 μm, the skin-depth due to the conductor structure is neglected. So, the bandwidth of the interconnection (for on-chip interconnection) is mainly dependent on the material loss tangent (dielectric loss).

It is very straight forward that increasing the bandwidth can be possible using of the material having lower loss tangent. However, in this case, new IC material development is necessary. Besides, manufacturing process is also needed to develop compatible to new IC materials.

Much work can be found in both on-chip interconnection technologies focusing on the material development. As for example, in on-chip interconnection, low-K (dielectric constant) and low loss tangent materials are under development stage, to achieve lower dielectric constant than non-doped silicon oxide. Lowering the dielectric constant than silicon oxide is possible in some extending from material characteristic point view, which is not long-term technique, and beyond that different materials are necessary. Besides, implementing new material in chip fabrication process will cost tremendously to make it mature. Having low-K (and low loss-tangent) material for on-chip interconnection is not only time consuming development, but also the costly short-term solution. In addition, implementing new material would reduce the reliability of the chip. It is highly desirable to have the high speed interconnects technology which could use the conventional material and standard manufacturing technology. Implementing such interconnect technology on-chip interconnects makes the chip highly reliable and would not need to pay high cost.

As explained above, the conventional electronics interconnect technology being used in on-chip interconnection cannot be used, as the need of the signal speed is increasing. Existing conventional electrical interconnects have the limitation of achieving the bandwidth in certain level, beyond that, either new low loss-tangent material development is necessary or new interconnect technology using conventional material is required. Developing low-loss tangent material and its related manufacturing process for IC build-up require high investment and time. It is highly desirable to have the innovative interconnect technology, which would use conventional material and conventional manufacturing process, but lower effective loss tangent. This technique or technology can be easily implemented as they can use the standard dielectric material used in IC industries.

### SUMMARY OF THE INVENTION

Accordingly, it is an object of the invention to provide the technique to reduce the effective loss-tangent of the on-chip interconnection system material to increase the bandwidth. Reducing effective loss-tangent reduces the microwave loss induced due to the dielectric material.

According to the invention it is an object of this invention to provide the interconnection structure to reduce the microwave-loss by adopting the interconnection structure.

According to the invention it is an object of this invention to use the conventional dielectric materials frequently used in the on-chip interconnects.

Another object of this invention is to provide the manufacturing process of the interconnects for on-chip interconnections using the conventional IC manufacturing technology.

It is also object of this invention to provide the structure of the interconnects which can increase the electrical signal propagation speed closer to the light.

According to the invention, the interconnects system comprises,
(i) single or multiple electrical conductors for carrying the electrical signal from one electronics elements to another and vice-versa for electrical communication;
(ii) a dielectric system comprising with (a) periodic arrays of dielectric spheres or cylinder with certain diameter and the pitch, located outside the electrical signal line (conductor), and designed to handle the signal frequency;
(iii) a ground or power line opposite side of the dielectric system, and;
wherein the shape of the periodic dielectric structure could be the square or hexagonal or the shape convenient in the manufacturing.

According to the invention, the interconnection system for on-chip interconnects comprises,
(i) single or multiple electrical signal lines for carrying the electrical signal from one electronics elements (e.g. transistor) to another and vice-versa for electrical communication;
(ii) a first dielectric system comprising with the opened trenches located below the signal line and passing along the signal lines, wherein the shape of the trenches are the quadrateral, or square or rectangular or circular, or the shape convenient to the manufacturing process, and the trenches are filled with air or vacuum or low loss-tangent material, and;
(iii) a ground or power line located opposite side of the first dielectric system, or the separate second dielectric system carrying the ground or power line attached with the first dielectric system.

According to the invention, the interconnection system for on-chip interconnects comprises,
(i) a ground or power (metal) line
(ii) a first dielectric system having opened trenches, wherein the shape of the trenches are the quadrateral, or square or rectangular or circular, or the shape convenient in the manufacturing, and the trenches are filled with air or vacuum or low loss-tangent material;
(iii) single or multiple electrical (metal) signal lines for carrying the high speed electrical signal from one electronics elements to another and vice-versa for electrical communication;
(iv) a second dielectric systems comprises with the opened trenches located below the signal line and pass along the signal lines, wherein the shape of the trenches are the quadrateral, or square or rectangular or circular, or the shape convenient in the manufacturing and the trenches are filled with air or vacuum, and;
(v) a third dielectric system carrying the ground or power line in one side;
wherein the first, second, and third dielectric systems with the signal lines and power or ground lines are attached together to form the interconnects.

According to this invention, the trench under the signal lines can be opened in such as way that full or portion of the dielectric material can be removed, and opened trench's deepness and wideness are dependent on bandwidth requirement.

According to this invention, single trench can be opened for each signal line.

Alternatively, according to this invention, a wide trench can be made for two or more signal lines close proximity to each other.

According to the invention, the interconnects system comprises,
(i) a ground or power line in one side of the uniform dielectric system;
(ii) a first comb-shaped dielectric system comprising (a) a series of the teethes with certain thickness and with a certain separation between the teeth, located one side of the second dielectric, (b) uniform dielectric layer left, and (c) the single or multiple signal lines located opposite side of the dielectric system, wherein the shape of space between each teeth is quadrateral, or square or rectangular or circular, or the shape convenient in the manufacturing, and the spaces are filled with air or vacuum or low dielectric constant and low loss tangent material, and;
(iii) a second comb-shaped dielectric system comprising (a) a series of the teethes with certain thickness and with a certain separation between the teeth, located one side of the dielectric, (b) uniform dielectric layer left, and (c) a ground or power plan, wherein the shape of space between each teeth is quadrateral, or square or rectangular or circular, or the shape convenient in the manufacturing, and the spaces are filled with air or vacuum or low dielectric constant and low loss tangent material;
wherein uniform dielectric system, first comb-shaped dielectric system, and second comb-shaped dielectric systems are stacked together to make the stripline type of configuration, and air-pocket created between the teethes along the direction of the signal lines helps to reduce the effective loss-tangent and increase the signal carrying capacity of the interconnects.

According to this invention, the air pockets created in between the teeth in each comb-shaped dielectric system can be aligned parallel or perpendicular in direction to each other when making the stack together to form the stripline configuration.

According to the invention, the interconnects system comprises,
(i) a comb-shaped dielectric system comprising (a) a series of the teethes with certain thickness and with a certain separation between the teethe, located one side of the dielectric, (b) uniform dielectric layer left, and (c) the single or multiple signal lines located opposite side of the dielectric system either in parallel or perpendicular in direction along the teeth direction, wherein the shape of space between each teeth is quadrateral, or square or rectangular or circular, or the shape convenient in the manufacturing, and the spaces are filled with air or vacuum or low dielectric constant and low loss tangent material, and;
(ii) a uniform dielectric system carrying the ground or power plans;
wherein the two dielectric systems are stacked together to make the microstrip line type of configuration, and air-pocket created between the teethes along or perpendicular in direction of the signal lines under the signal lines, helps to reduce the microwave loss and increase the signal carrying capacity of the interconnects.

According to this invention, signal lines could be arranged as single ended or in differential pairs side-by-side, and each layer can have the single or multiple signal lines.

Again, according to this invention, only single ground plan or single power plan can be used for each signal plan.

According to this invention, multiple layers, in each of which has either ground/power line or signal lines, stacked together to form the multi-layered IC.

According to this invention, opened trench of the dielectric system can be filled up with the air or kept vacuum, or alternatively filled by the liquid crystal, wherein the loss-tangent (and also dielectric constant) inside the trenches can be changed based on the electrical field, resulting in the tunable of the effective loss-tangent (and also effective dielectric constant).

Alternatively, according to the invention, the opened trench of the dielectric system is filled with photonics crystal or electronics crystal system, consisting of the periodic arrays of the dielectric sphere or cylinder with diameter and lattice constant, wherein the electromagnetic wave is propagated inhomogeneous, but non-dissipation dielectric media.

Alternatively, according to the invention, the photonics crystal or electronics crystal system could be quasi photonic (or electronic) crystal system, consisting of the single layer or multiple layers of the photonic crystals and single or multiple layers of uniform dielectric layers.

According to the invention, the interconnects system comprises,
(i) single or multiple electrical signal lines (conductors) for carrying the electrical signal from one electronics elements to another and vice-versa for electrical communication;
(ii) a dielectric system comprising with the periodic arrays of air spheres or cylinder with certain diameter and the pitch into the dielectric medium, located outside and underneath the electrical signal line (conductor), and designed to handle the signal frequency, and;
(iii) a ground or power line opposite side of the dielectric system;
wherein the shape of the periodic dielectric structure could be the square or hexagonal or the shape convenient in the manufacturing.

According to this invention, dielectric system consists of the periodic arrays of the air hole with certain diameter and pitch into the dielectric medium, and located outside of the electrical signal line (conductor).

According to this invention, dielectric system consists of the periodic arrays of the air hole with certain diameter and pitch into the dielectric medium, located outside of the electrical signal line (conductor), and the hole is alternatively filled by the liquid crystal, wherein the dielectric constant inside the hole can be changed based on the applied electrical field, resulting in the tunable of the effective dielectric constant.

According to the invention, the dielectric system, alternatively, is based on the photonics crystal or electronics crystal system, consisting of the periodic arrays of the dielectric sphere or cylinder with diameter and lattice constant, wherein the electromagnetic wave is propagated inhomogeneous, but non-dissipation dielectric media.

Alternatively, according to the invention, the photonics crystal or electronics crystal system could be quasi photonic (or electronic) crystal system, consisting of the single layer or multiple layers of the photonic crystals and single or multiple layers of uniform dielectric layers.

According to this invention, the dielectric system is designed alternatively based on the photonic band-gap or electronic bad-gap principle or their quasi principle.

According to this invention, the electrical signal line could be microstrip type or strip line type or coplanar type waveguide.

According to this invention, the effective dielectric constant and effective loss tangent of the dielectric system is reduced, which reduce the microwave-loss and makes to increase the bandwidth of the interconnection. The lower the microwave loss, the closer the signal speed to the speed of the light.

The invention offers to connect the signal line of one electronics elements to other electronic elements to communicate without sacrificing each electronic element's signal speed. These inventions could be easily implementable using today's manufacturing technology and conventional dielectric materials. The methods described in this disclosure enables to make the electronics interconnects for on-chip, connection in cost-effective manner and suitable for practical application. These inventions also used to high-speed (bandwidth) electronic connector, and cable where two or more electronic elements are to be connected.

According to this invention, the interconnects with opened-trench can be used to transmit the optical signal through the air or vacuum or low loss-tangent material, filled the trench. In that case, ultra high speed interconnects comprising with electrical and optical signals can be achieved. As the same trench can be used for both electrical and optical interconnects, high density can be achieved for high-speed transmission.

Another advantages of this invention is that the trench of the proposed interconnects can also be used for cooling the interconnects or IC. The trench can be filled with the coolant or gas to dissipate the heat generated due to electrical signal flowing through the electrical signal lines or heat generated due to the other active (e.g. transistor) and passive (resistor) component's power consumption.

The other object of this invention is to minimize the skew in the signal interconnection, occurred due to the signal propagation delay, by reducing the loss-tangent.

Other objects, features, and advantages of the present invention will be apparent from the accompanying drawings and from the detailed description that follows below.

### BRIEF DESCRIPTION OF THE DRAWINGS

The invention will be explained in more detail in conjunction with the appended drawings wherein:

FIG. 1 is the cross-sectional view showing the prior art intra-chip (on-chip) electrical interconnection. For simplicity, part of the Si based MOS-transistors and their electrical interconnection is shown;

FIGS. 2A and 2B are the simplified cross-sectional views of the microstrip and stripline transmission line. This is an explanatory diagram showing the prior-art based on which today's electronic interconnection is made;

FIG. 3A is the top view, and FIGS. 3B and 3C are the cross-sectional views taken along AA′ section, illustrating two microstrip configurations on the dielectric system having back trenches for electrical interconnects in a first preferred embodiment according to the invention;

FIGS. 4A, 4B, 4C, 4D, 4E, and 4F are the cross-sectional views, illustrating different microstrip and stripline configurations, respectively on the dielectric system having back trenches (and (front trenches) for electrical interconnects in a second preferred embodiment according to the invention. The microwave losses due to the dielectrics are dependent on the physical parameters such as width W, height H, deepness of the trenches H/n, where n is the integer and equal to 1, 2, 3, and so on, etc.;

FIG. 5A is the schematic showing the on-chip electrical interconnection having high bandwidth. FIG. 5B is the schematic showing the cross-sectional view along the direction B-B′ of FIG. 5A in a third preferred embodiment in accordance with the invention. opened trenches are used to reduce the effective dielectric constant and effective loss tangent. For simplicity, two transistors and their electrical interconnection are shown;

FIGS. 6A, 6B, 6C, and 6D are the cross-sectional views illustrating the fabrication process of high-signal carrying capacity interconnects for on-chip interconnects in a fourth preferred embodiment in accordance with the invention. For simplicity only one interconnects is shown. The interconnects can be the microstrip type or strip line type interconnects or just the metal line on the dielectric without considering the certain characteristic impedance. The trench or void can be filled up by the air or kept vacuum, or by other dielectric material;

FIGS. 7A, 7B, and 7C are the cross-sectional views illustrating the different type of on-chip interconnects configuration with opened trenches into multiple dielectric system combinations, in the fifth preferred embodiment in accordance with the present invention. The trenches can be filled up by the air or kept vacuum, or by other dielectric material;

FIG. 8 is the schematic showing the on-chip electrical interconnection having high bandwidth, in a sixth preferred embodiment in accordance with the invention. For simplicity, two transistors and their electrical interconnection are shown. The hole can be filled up by the air or kept vacuum, or by other dielectric material;

FIGS. 9A, 9B, 9C, 9D, 9E, 9F, 9G, and 9H are the enlarged cross-sectional views, illustrating the fabrication process of high-signal carrying capacity on-chip interconnects in a seventh preferred embodiment in accordance with the invention. For simplicity only one interconnects is shown. The interconnects are based on the type of interconnects as shown in FIG. 8. The hole can be filled up by the air or kept vacuum, or by other dielectric material;

FIG. 10 is the schematic showing the on-chip electrical interconnection having high bandwidth, in a eighth preferred embodiment in accordance with the invention. The difference between FIGS. 8 and 10 are that multiple column of air spheres or cylinder are made over the dielectric system to form the quasi or complete photonics crystal like structure. Without having photonics crystal, the formation of air spheres into the dielectric system reduces the effective dielectric constant and effective loss tangent. For simplicity, two transistors and their electrical interconnection are shown. The hole can be filled up by the air or kept vacuum, or by other dielectric material;

FIGS. 11A, 11B, 11C, 11D, 11E, 11F, 11G, and 11H are the enlarged cross-sectional views illustrating the fabrication process of high-signal carrying capacity on-chip interconnects in ninth preferred embodiment in accordance with the invention. For simplicity only one interconnects is shown. The interconnects are based on the type of interconnects as shown in FIG. 10. The hole can be filled up by the air or kept vacuum, or by other dielectric material;

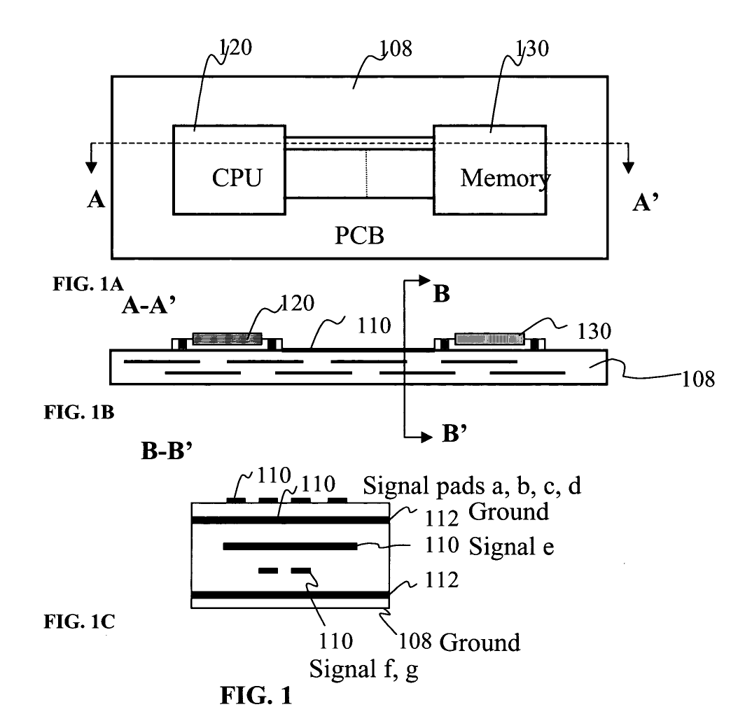

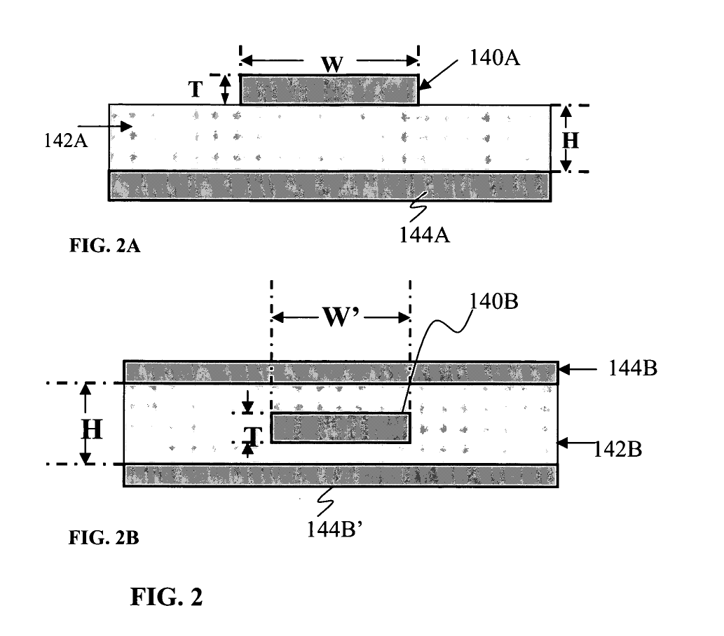

### DESCRIPTION OF THE PREFERRED EMBODIMENTS

The best modes for carrying out the present invention will be described in turn with reference to the accompanying drawings. In the following description, the same reference numerals denote components having substantially the same functions and arrangements, and duplicate explanation will be made only where necessary.

An important point of high speed electronic interconnects system (for on-chip) according to the invention is that the microwave loss induced due to the dielectrics is to be reduced by reducing the effective loss-tangent of the dielectrics, resulting in increasing the signal carrying capacity of the interconnects. In doing so, the main point is kept into mind that the technique is to be cost effective, and compatible to standard manufacturing technology.

It is very straight forward that increasing interconnects (on-chip) bandwidth can be possible by using of the low loss-tangent material. However, new materials and related manufacturing technologies are to be developed to implement practical interconnects. It is highly desirable to invent the interconnects which have low effective loss-tangent, and which could use conventional manufacturing technology.

In the preferred embodiments explanation, first several interconnects structures (techniques) to reduce the effective loss-tangent will be explained considering the single signal line with specific characteristics impedance, and later part of this section cover the process and applications of the preferred embodiments.

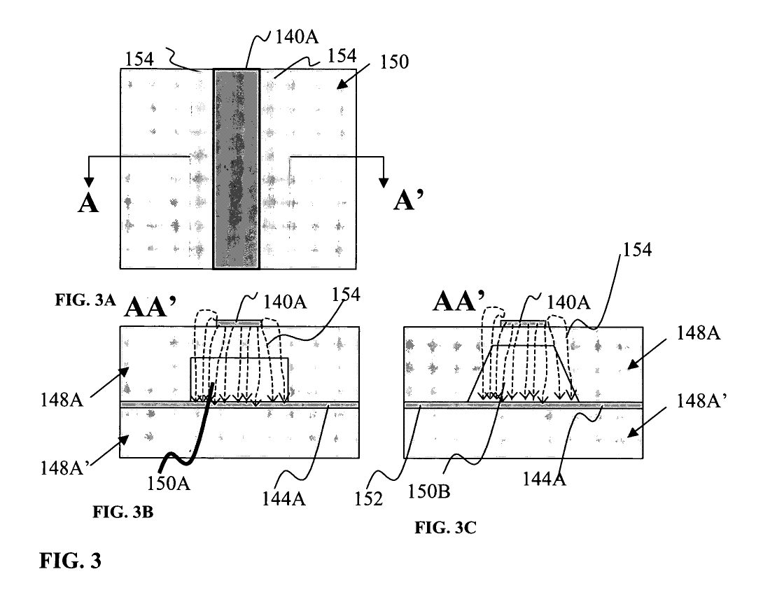

FIG. 3A is the top view and the FIGS. 3B and 3C are the cross-sectional views of a portion of the interconnects system, taken along AA′ direction of FIG. 3A in the first embodiment in accordance with the invention, wherein the same numerals represents the same parts so that repeated explanation is omitted here. Microstrip line as shown in FIG. 3A is laid onto dielectric system 148, having the opened trenches 150 A (or 150B) into the dielectric system 148 located at the backside of the signal line 140A. The ground plan 152 is located on other dielectric system 148A′. The shape of the opened trenches 150A (and 150B) could be tetrahedral (square, rectangular or circular) or any shapes convenient to manufacturing process, and the trenches are filled with the air or kept vacuum, or by any dielectric materials having lower loss tangent (and/or by lower dielectric constant). This could be filled with the liquid crystal. By doing this, the refractive index can be tuned based on the electrical field. While signal flowing through the transmission line 140A (conductor), the electrical field 154 (and also magnetic field (not shown)) passes through the opened trenches and dielectric system 148A left under the transmission line 140A. As the electrical field 154 is passing through the opened trenches containing the air and the less dielectric layer, the effective dielectric constant and effective loss tangent of the structure as shown in FIG. 3, gets much more lower than those of actual dielectric material used in dielectric system 148 A. This results in reducing the microwave loss (experienced due to the dielectrics) as compared with that of the conventional uniform dielectric system (not shown). In other words, signal transmission is less dispersive, and higher bandwidth of the interconnects system is ascertained, as compared with the conventional interconnects where signal conductor is laid onto the uniform dielectric medium.

Based on the shape and physical parameters of the opened trenches, the microwave loss experienced due to the dielectric system, can be made as low as close to the air. In the preferred embodiment, the dielectric is left under the conductor, to reduce microwave loss as close to air, the opened trenches could be extended to the conductor.

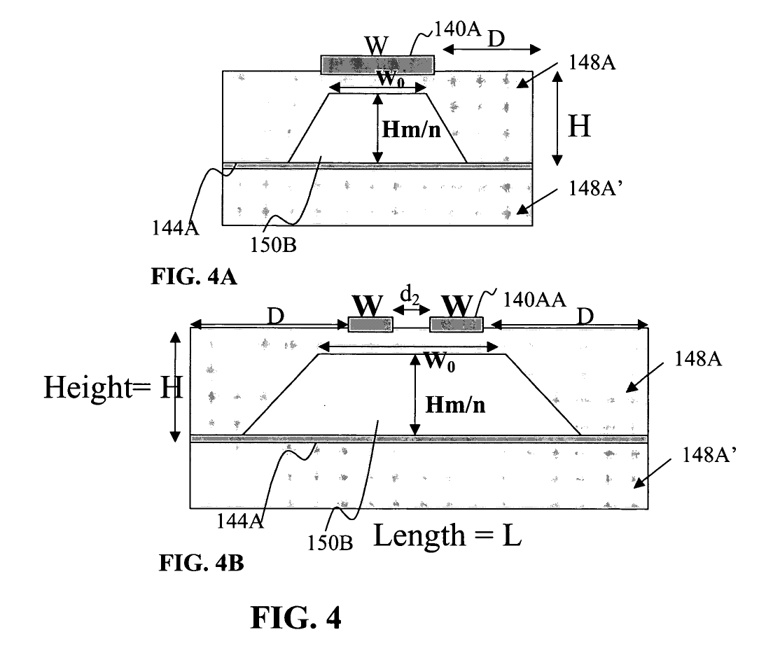

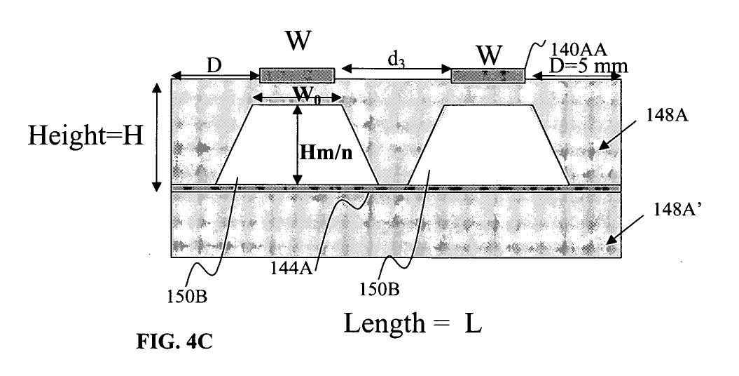

FIGS. 4A, 4B, and 4C are the cross-sectional views, illustrating different microstrip configurations on the dielectric system having back trenches for electrical interconnects and FIGS. 4D, 4E, and 4C are the cross-sectional views, illustrating different strip line configurations on the dielectric system having opened top and back trenches for in a second preferred embodiment according to the invention, wherein the same numerals represent the same parts so that repeated explanations are omitted here. Different mircostrip lines structures such as single ended and differential pars with opened trenches are shown. For simplicity, single pairs and also single-ended (single channel) microstrip type signal lines are shown, but in actual application multiple signal lines could also be used in multilayered dielectric layers. The microwave losses of the signal lines are dependent on (a) conductor width W 140A (designed to have close to 50 ohm for the single-ended, and close to 100 ohm for the differential pairs lines) and (b) trench 150B parameters such as dielectric height (from ground plan to conductor) H, deepness of the trenches Hm/n, where n and m are the integer and equal to 1, 2, 3, and so on. For the differential pair lines, space between the differential line (d₂ or d₃) determines the microwave loss. Optimizing the each factors, will determine the low microwave loss and low signal propagation delay. For simplicity one type of trenches are shown here, but it can cover other shapes of the trench such as square, rectangular, or circular, or the shape convenient to manufacturing. Again, here the trench is filled with the air (or gas) or kept vacuum, but other dielectric materials with suitable dielectric constant and loss tangent can also fill it.

In FIGS. 4D, 4E, and 4C, the microwave losses induced due to the dielectrics are dependent on the (a) conductor width W 140B (designed to have close to 50 ohm for the single-ended, and close to 100 ohm for the differential pairs lines) and (b) opened trenches 150B parameters such as dielectric height (from ground plan to conductor) H₁ and H₂, deepness of the trenches Hm/n, where n and m are the integer and equal to 1, 2, 3, and so on. For the differential pair lines, space between the differential line (d₂ or d₃) determines the microwave loss. Optimizing the each factors, will determine the interconnects bandwidth and signal propagation delay. For simplicity one type of trenches are shown here, but it can cover other shapes of the trench such as quadrateral, trapezoidal, square, rectangular, or circular, or the shape convenient to manufacturing. Again, here the trench is filled with the air, or kept vacuum, or other dielectric materials with suitable dielectric constant and low loss tangent can fill it.

According to this invention the effective dielectric constant (i.e. microwave index) and effective loss tangent is considerably decreased, and the electrical field intensity near to the signal line. The reason is as follows: (i) the electric field leaks out effectively into the backside (and also top trenches for the stripline case), so that the effective loss tangent decreases. For simplicity, signal lines consisting of the microstripline and stripline configurations are considered. Various coplanar configurations such as G-S-G, or G-S-S-G or G-S-G-S-G or G-S-S-S-G etc. having opened trenches also cover this invention.

Dielectric material, which can be used for this purpose, includes all kinds of dielectric and ceramics materials such as SiO₂, SiN, FR4, Duroid, AlN Al₂O₃, BN, SiC, BeO, and all kinds of low temperature co-fired ceramics etc. All kinds of polymer materials having dielectric properties falls also under this dielectric material. These dielectric materials can be made using high (or low) temperature ceramics processing or using the IC fabrication process.

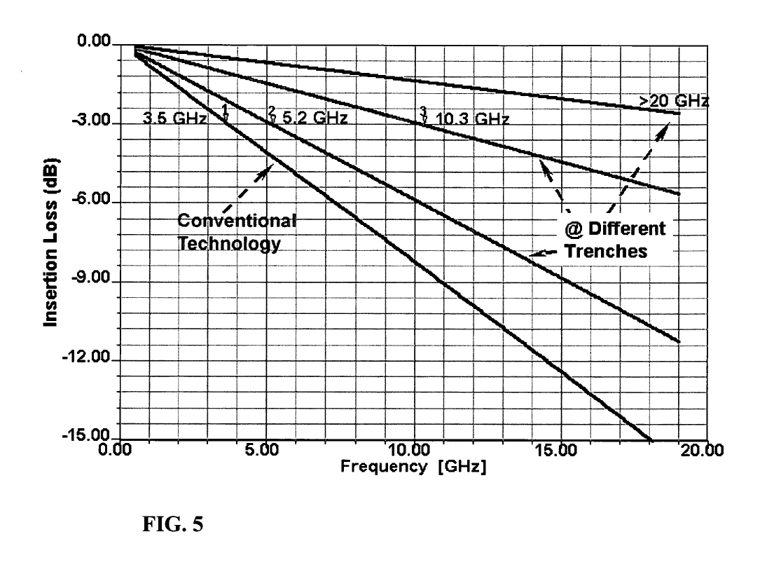

FIG. 5A is the schematic showing the on-chip electrical interconnection having high bandwidth. FIG. 5B is the schematic showing the cross-sectional view along the direction B-B′ of FIG. 5A in a third preferred embodiment in accordance with the invention. Opened trench is used to reduce the effective dielectric constant and effective loss tangent. For simplicity, two transistors and their electrical interconnection are shown. In the preferred embodiment, electronic MOS (metal-oxide semiconductor)-device 102 on semiconductor substrate 100 (e.g. silicon) is connecting with other electronic device (not shown) by signal line 104A. Plurality of electronics devices on semiconductor substrate (for example, Si (100)) can be interconnected by signal lines like 104A and 104B. The signal line 104A (and also 104B) is made on the dielectric system 106A, in which the trench 170 is opened under the signal lines. The signal line can be transmission line maintaining the characteristic impedance as desired or the just the metal interconnects on the dielectric system 106A. The portion of the dielectric 172 over which the signal line is to be laid, are kept uniform. The trench can be made inside the dielectric layer 106A system by single or multiple processes using the standard IC fabrication technology.

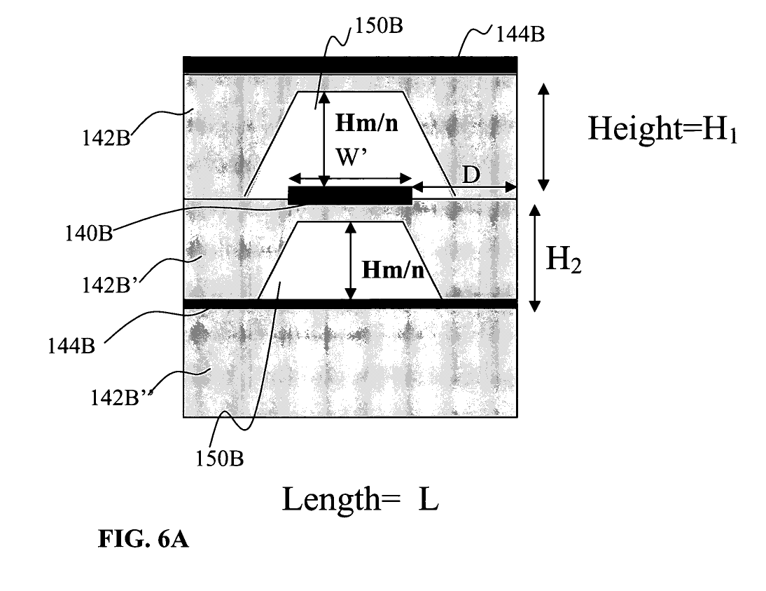

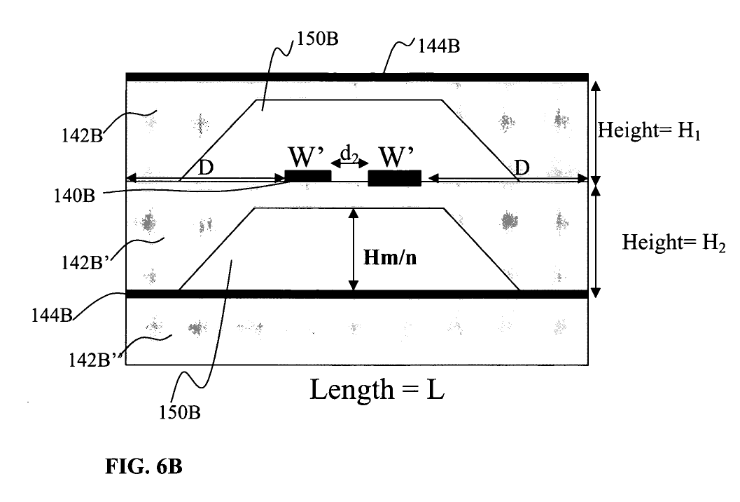

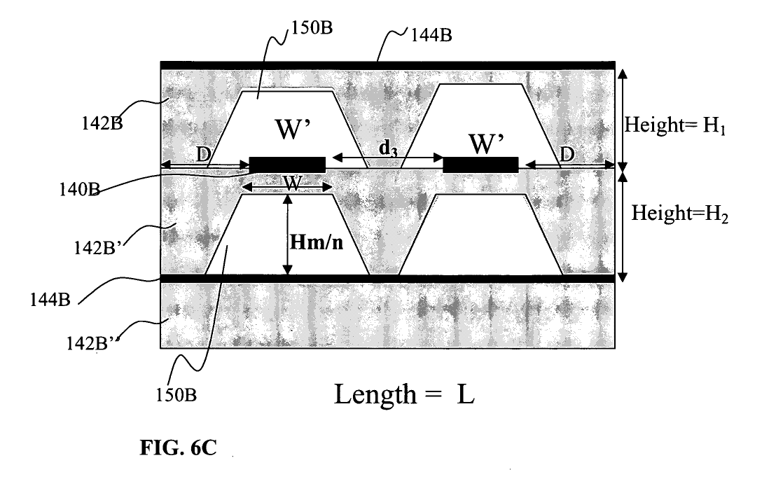

FIGS. 6A, 6B, 6C, and 6D are the cross-sectional views illustrating the fabrication process of high-signal carrying capacity interconnects for on-chip interconnects in a fourth preferred embodiment in accordance with the invention, wherein like parts are indicated by like reference numerals as used in FIG. 5, so that repeated explanation is omitted here. For simplicity in figure, single layer and single line interconnects in on-chip interconnects are considered. Similar process can be used for fabricating large scale on-chip interconnect systems. For simplicity, only one interconnects is shown. The interconnects can be the microstrip type or strip line type interconnects or just the metal line on the dielectric without considering the certain characteristic impedance. The trench or void can be filled up by the air or by other dielectric material.

The dielectric layer 106 is deposited using standard IC fabrication technology such as chemical vapor deposition (CVD), or sputtering, or evaporation technique. After making patterns using standard photolithography technology, the two lines 174 with high aspect ratio is made using the dry-etching (or wet-etching) technology such as reactive ion beam etching (RIBE), reactive ion etching (RIE), or milling etc. This is followed by the dielectric layer 176 formations on 106. After chemical-mechanical polishing (CMP) the planarization is possible. The deposition of the 176 made the trench like void 178 under the dielectric layer 176 in between the two lines 174. Subsequent patterning and metallization can make the signal lines, which connect the electronics devices on-chip.

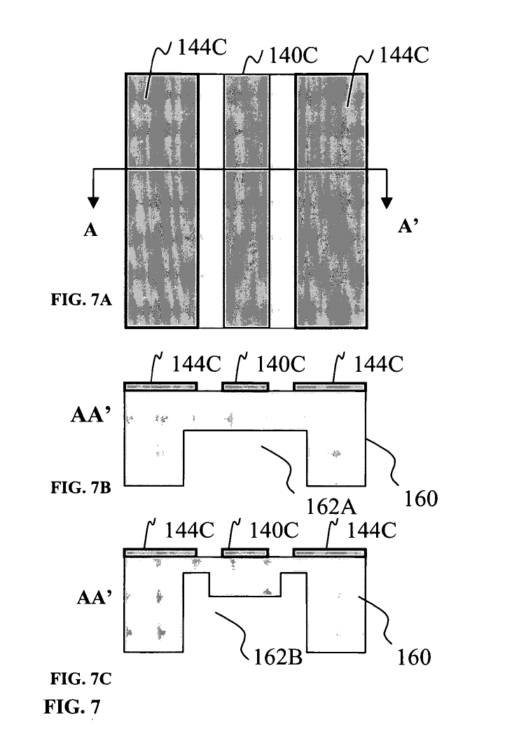

FIGS. 7A, 7B, and 7C are the cross-sectional views illustrating the different type of on-chip interconnects configuration with opened trenches into multiple dielectric system combinations, in the fifth preferred embodiment in accordance with the present invention, wherein like parts are indicated by like reference numerals as used in FIG. 5, so that repeated explanation is omitted here. Here different type signal lines (180, 182, or 184) with backside trenches as explained previously are shown on-chip. For making the microstrip line or strip line type, ground conductor 186 can be used. For fabrication of the signal line of strip line type 184, multiple steps process can be necessary, as explained in FIG. 6. The making trench and the metallization for making the signal line or ground are the same as explained in FIG. 6, so that repeated explanation is omitted here.

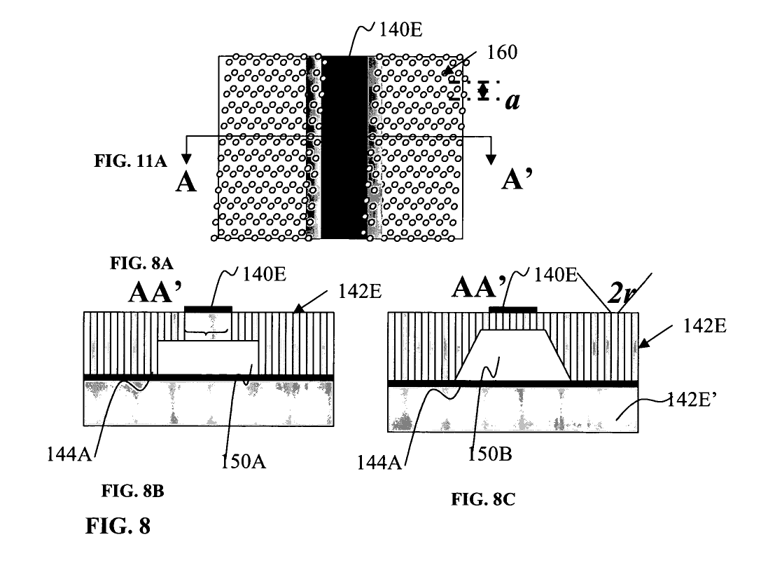

FIG. 8 is the schematic showing alternative way of on-chip electrical interconnection having high bandwidth, based on the interconnects configuration as shown in FIGS. 3 and 4, in a sixth preferred embodiment in accordance with the invention, wherein like parts are indicated by like reference numerals as used in FIGS. 5, 6 and 7, so that repeated explanation is omitted here. In the preferred embodiment, electronic MOS (metal-oxide semiconductor)-device or other semiconductor electronics elements 102 on semiconductor substrate 100 (e.g. silicon) are connecting with other electronic device (not shown) by signal line 104A. Plurality of electronics devices on semiconductor substrate (for example Si (100)) can be interconnected by signal lines like 104A and 104B. The signal line 104A (and also 104B) is made on the dielectric system 106 and 106A (for multiplayer contacts), on which array of the air holes 188 are made. The signal line can be transmission line maintaining the characteristic impedance as desired or the just the metal interconnects on the dielectric system 106A. The air spheres 188 are opened only near to the signal line to reduce the fringing field. To reduce further effective dielectric constant and loss tangent, the air spheres 188 can be opened at the bottom of the signal line (not shown). Noted here that the array of air holes can be made using the same process of VIA opening for the contacts. The opened hole is filled with air or other dielectric material to tune the dielectric constant as desired based on the shape and density of the air holes (into the dielectric). Multiple dielectric layers (not shown) can also be used which comprising the homogeneous dielectric layer and inhomogeneous dielectric layer with air holes.

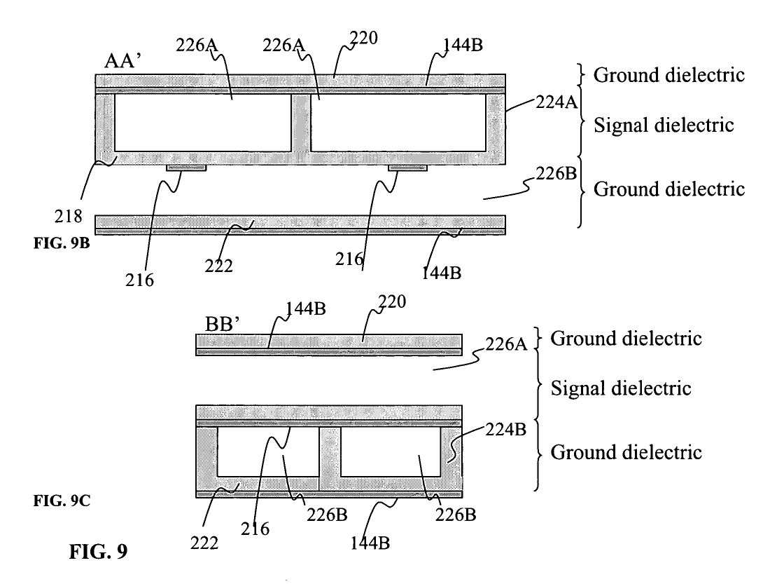

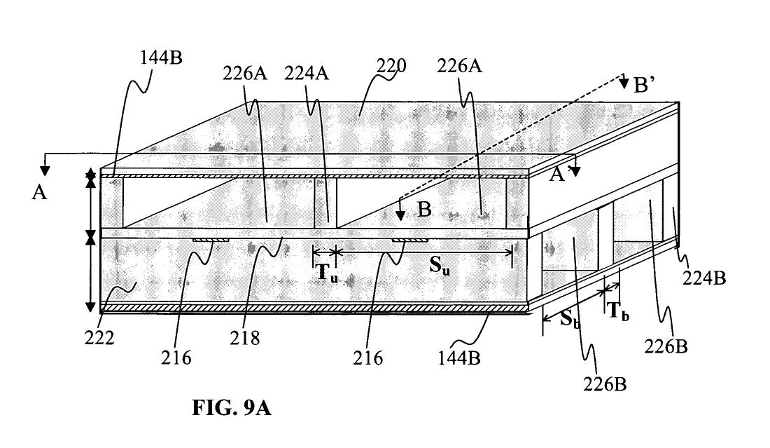

FIGS. 9A, 9B, 9C, 9D, 9E, 9F, 9G, and 9H are the enlarged cross-sectional views, illustrating the fabrication process of high-signal carrying capacity on-chip interconnects in a seventh preferred embodiment in accordance with the invention, wherein like parts are indicated by like reference numerals as used in FIGS. 5, 6, 7, and 8, so that repeated explanation is omitted here. The interconnects are based on the type of interconnects as shown in FIG. 8. For simplicity in figure, single layer and single line interconnects in on-chip interconnects are considered. Similar process can be used for fabricating large scale on-chip interconnect systems. For simplicity, only one interconnects is shown. The interconnects can be the microstrip type or strip line type interconnects or just the metal line on the dielectric without considering the certain characteristic impedance. The trench or void can be filled up by the air or by other dielectric material.

The dielectric layer 106 is deposited using standard IC fabrication technology such as chemical vapor deposition (CVD), or sputtering, or evaporation technique. The difference between technique for reducing the effective dielectric constant and effective loss tangent as explained in FIG. 7 and FIG. 9 are that the periodic air spheres (cylindrical) array 188 are opened into the dielectrics 106 and 106A (for multi layer contacts) on which the metal conductors (signal line) are to be laid. The air spheres 188 are opened only near to the signal line to reduce the fringing field. To reduce further effective dielectric constant and loss tangent, the air spheres 188 can be opened at the bottom of the signal line (not shown). Alternatively, air-holes can be made in two dielectric layers (not shown) instead of single dielectric layer, in which first layer consists of the air-holes periodic structure into the dielectric system and second dielectric layer is thinner and metal electrode is mainly laid on. Noted here that the array of air holes can be made using the same process of VIA opening for the contacts. The opened-holes are filled with air or other dielectric material to tune the dielectric constant as desired based on the shape and density of the air holes (into the dielectric).

After the first dielectric layer 106 formations, subsequent photolithography and dry etching make the air hole into dielectric. Under a single process, VIA openings 190 for metal contact and air-spheres 188 into the dielectric can be made together. Following the photolithography for making the pattern of 192, and metallization make the metal conductor along with the metal contact 194. Similar process can be repeated for the multilayered metal contacts, as shown in FIGS. 9E, 9F, 9G, and 9H. As the fabrication process is the same, repeated explanation is omitted here. This is the one example of the fabrication process, this also cover other ways where air-holes spheres into the dielectric layer are used to for making high signal carrying capacity by reducing the effective dielectric constant and also reducing effective loss tangent of the dielectric system.

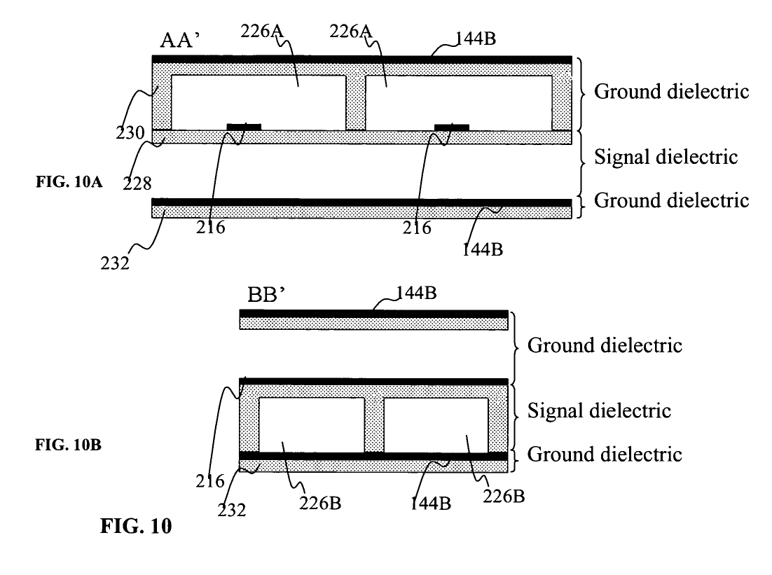

FIG. 10 is the schematic showing the on-chip electrical interconnection having high bandwidth, based on the interconnects configuration as shown in FIGS. 3 and 4, in a eighth preferred embodiment in accordance with the invention, wherein like parts are indicated by like reference numerals as used in FIGS. 8 and 9, so that repeated explanation is omitted here. The difference between FIGS. 8 and 10 are that multiple column of air spheres or cylinder 188 are made over the dielectric system to form the quasi or complete photonics crystal like structure. Making the photonic crystal or quasi-photonic crystal, the signal carrying capacity of the interconnects can be increased tremendously. As the dielectric constant and loss tangent of the dielectric system can be controlled over the area, other passive feature such as the controlling the signal propagation delay the skews of the interconnects can be reduced. Other passive features for example, pre-emphasis or equalization etc. is also possible utilizing the different dielectric constant feature over the surface. Noted here that the array of air holes can be made using the same VIA opening process for the contacts. The opened hole is filled with air or other dielectric material to tune the dielectric constant as desired based on the shape and density of the air holes (into the dielectric). Multiple dielectric layers (not shown) can also be used which comprising the homogeneous dielectric layer and inhomogeneous dielectric layer with air holes.

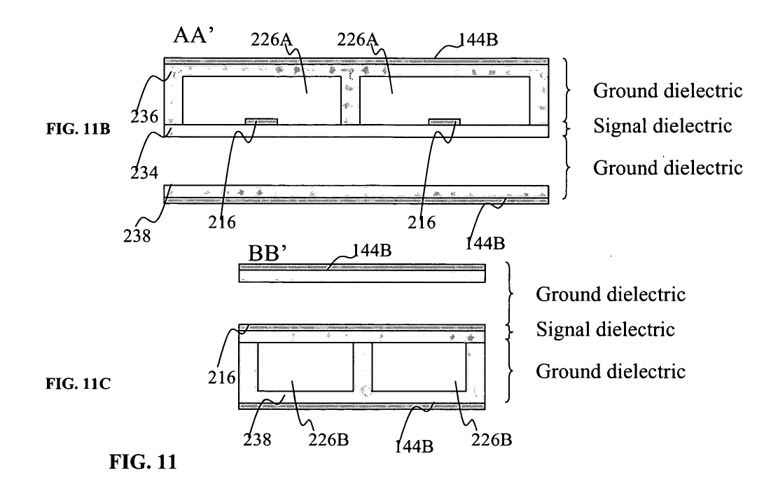

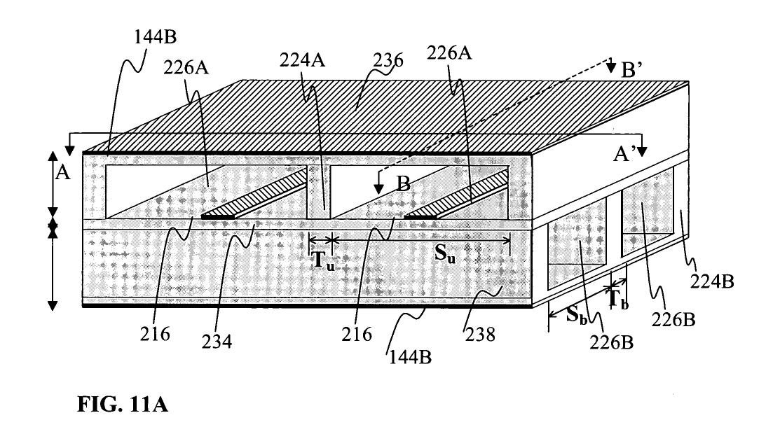

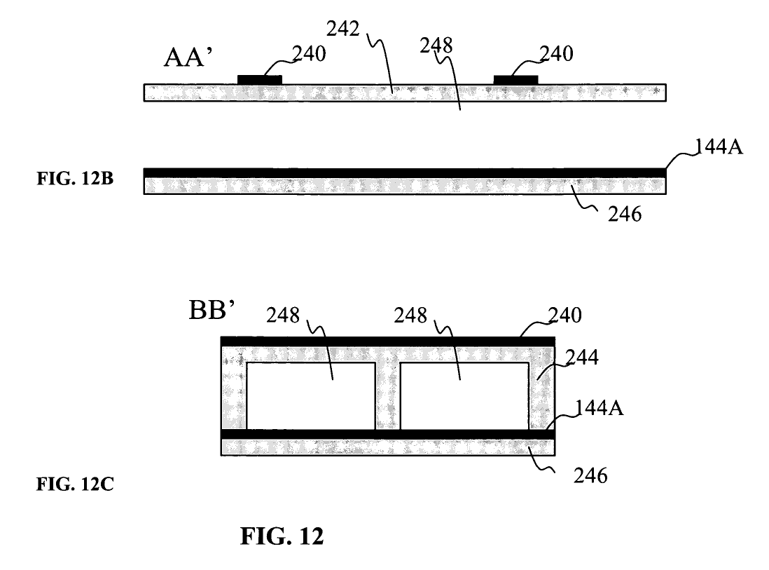

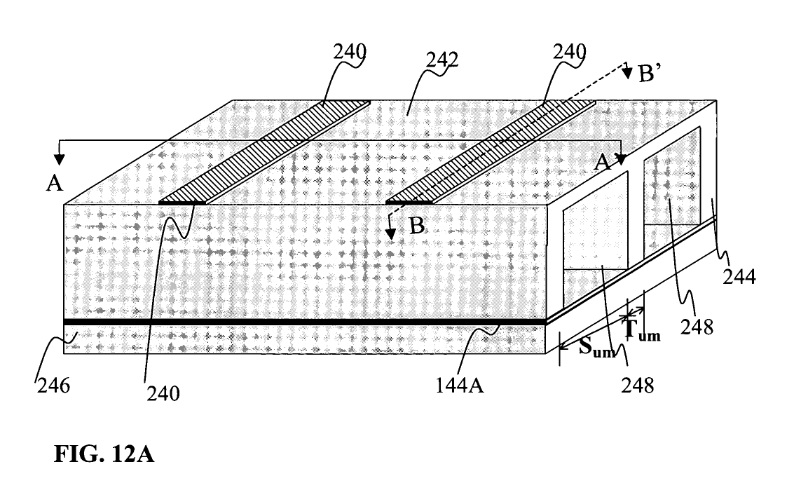

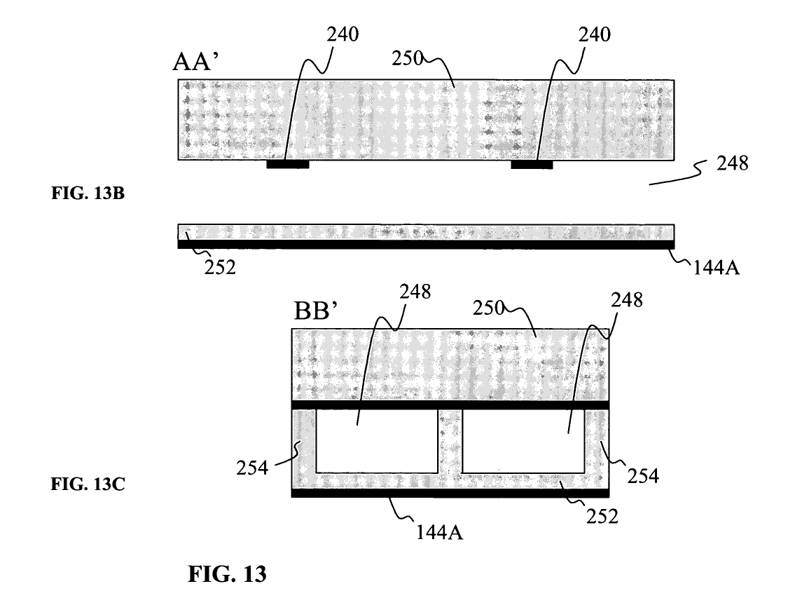

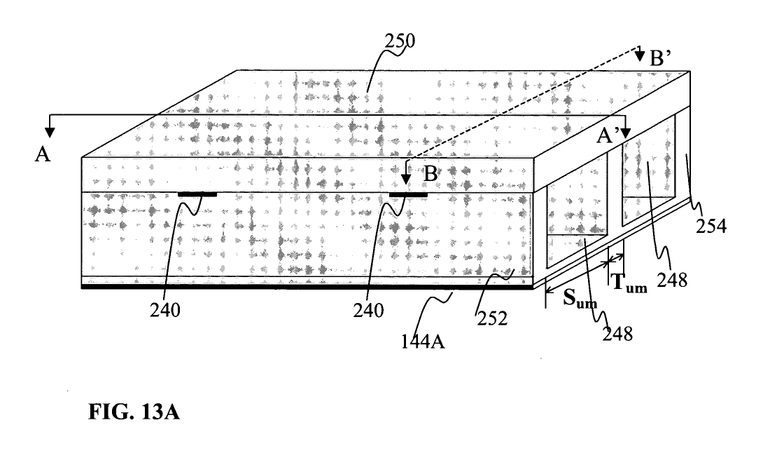

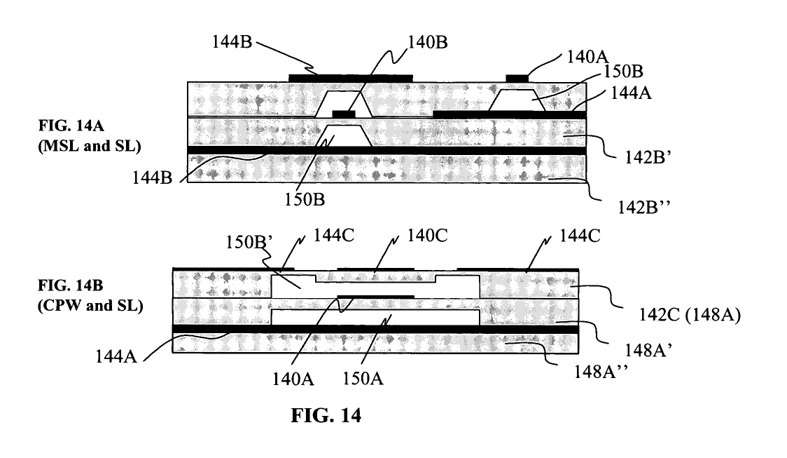

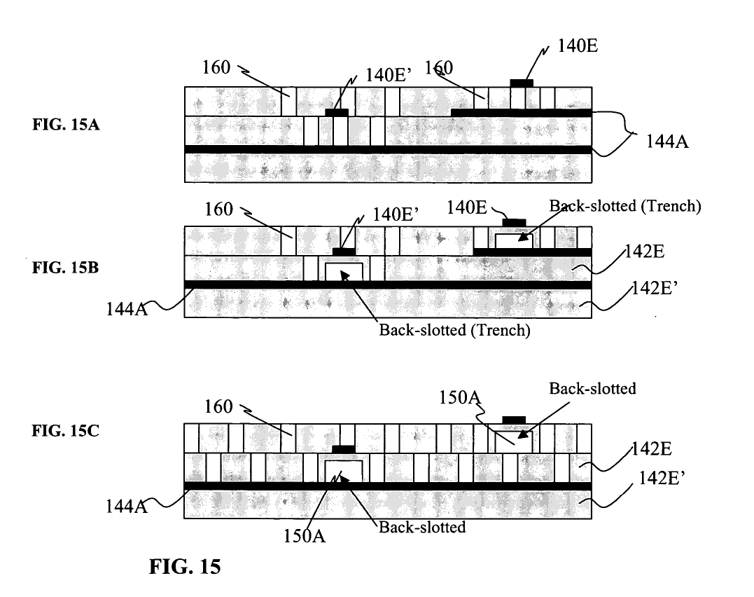

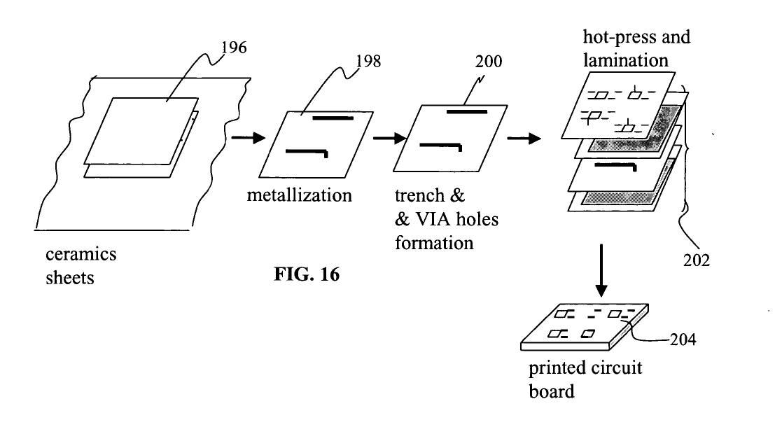

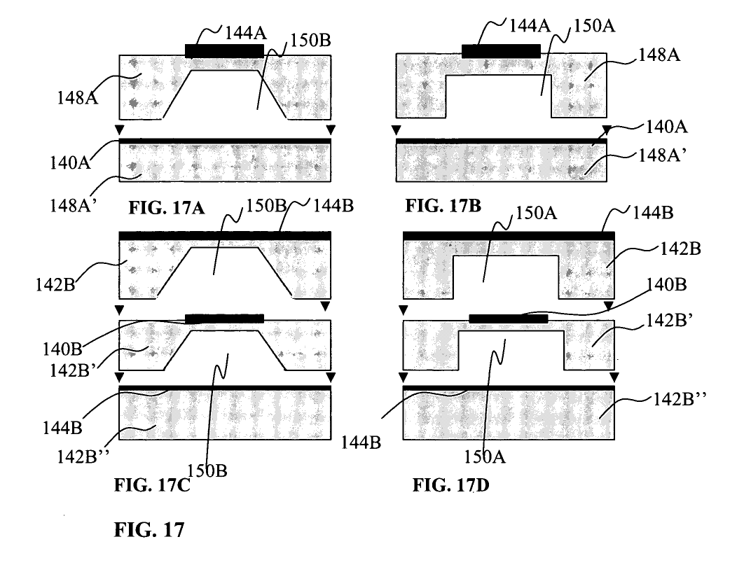

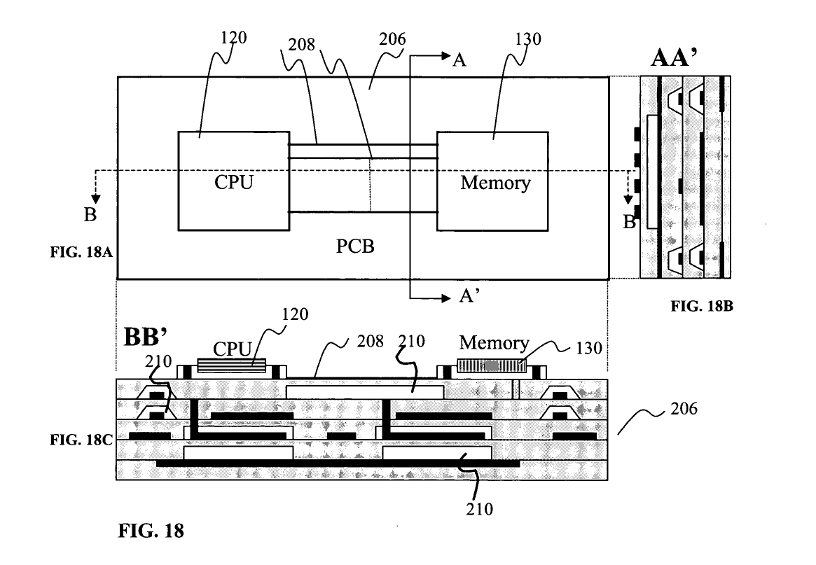

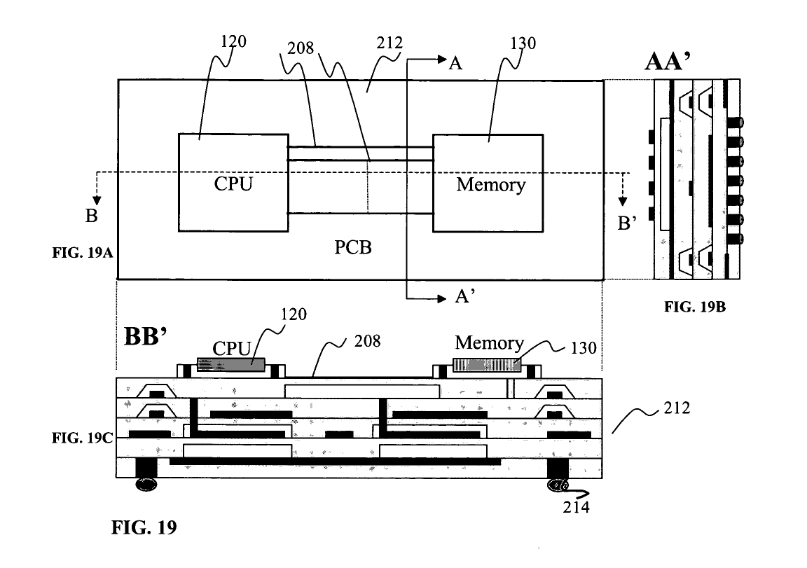

FIGS. 11A, 11B, 11C, 11D, 11E, 11F, 11G, and 11H are the enlarged cross-sectional views illustrating the fabrication process of high-signal carrying capacity on-chip interconnects in a ninth preferred embodiment in accordance with the invention, wherein like parts are indicated by like reference numerals as used in FIGS. 5, 6, 7, 8, and 9 so that repeated explanation is omitted here. In the preferred embodiments, the dielectric layers 106 and 106A have the periodic structure of air holes or spheres all over the dielectric layer. This is made to make the Photonics crystal or Photonics bandgap structure using the standard dielectric materials. The effective dielectric constant and effective loss tangent of the dielectric systems can be reduced and the interconnects signal carrying capacity can be increased tremendously. The fabrication process is same as the one as explained in FIG. 9, so that repeated explanation is omitted here. For simplicity only one interconnects is shown. The interconnects are based on the type of interconnects as shown in FIG. 10. The hole can be filled up by the air or by other dielectric material.

According to preferred embodiment, on-chip interconnects using the dielectric system can have single or multiple techniques (for reducing the microwave loss), as explained in FIGS. 3 thru 10. Backside trenches (microstrip line) or both side trenches (stripline) can be used in the dielectric system to reduce the effective dielectric constant and effective loss tangent. Alternatively, Air hole arrays can be used in the dielectric system. Alternatively also, the low dielectric constant material or the liquid crystal polymer fills up the hole. Dielectric materials include all kinds vapor deposited dielectric material such as silicon oxide, silicon nitride, silicon oxy-nitride, silicon carbide etc. Microporous silicon can also be used as dielectric layer 106 (or 106A). Dielectric materials also include all kinds of the vapor deposited or spin-coated polymers such as benzocyclobutene, acrylate based polymer, elastomer or monomer etc. In the preferred embodiments as explained in FIGS. 5, 8, 9, 10, and 11, metal conductor line on the dielectric system is considered as the signal line, the signal lines also includes microstrip, strip line, or coplanar line configuration with single or multiple signal lines (as single or differential). Dielectric coverage (not shown) using of the same or different dielectric material can be used.

According to the present invention, it is our object to control the electrical field to reduce the effective dielectric constant which thereby reducing the microwave loss and increasing the bandwidth of the interconnection system. In the preferred embodiments as explained above from FIGS. 3 to 11, single signal line in different microstrip line configurations are shown in the object of explaining the inventions. These inventions also cover single or multiple signal lines in strip line, coplanar-line configurations or simple metal conductor laid on the dielectric material for interconnects. Signal lines in these cases could be single or differential line.

It is noted here that the trench under the metal electrode or the periodic holes into the dielectric system can also be used for optical signal transmission; a viable high speed electrical and optical or optical interconnects solution for very high-speed on-chip interconnects. Comparatively high-speed electrical signal after converting into optical signal can be transmit through the trenches and the similar speed or slower speed can be sent through the electrical conductors laid on the dielectric system (not shown). Alternatively, periodic structure of air-holes unto the dielectric system or photonics crystal or quasi phonics structure can be used to transmit the optical signal through the dielectric and/or comparatively lower speed or similar speed electrical signal can be passed thought the electrical conductor laid on the dielectric system (not shown). These help to increase the high-speed interconnect density on-chip level.

According to this invention, the different feature for example, emphasize/equalization features can also be designed passively on-chip level by controlling the dielectric constant of the materials along the signal lines utilizing the dielectric systems comprising the single or multiple combination of the dielectrics as shown in FIGS. 3 to 4. The dielectric constant (and also the loss tangent) along the signal lines located in the dielectric system of the on-chip can be changed using the different hole or lattice size made into the dielectric system (in the case of photonics crystal or photonics bandgap materials) along the signal line(s). Alternatively, if the trenches are used, the dielectric constant/loss tangent can be changed using the different size and shape of the trenches along the signal line(s).

The spheres 188 array into the dielectric, as shown in FIGS. 8 and 11, could be air (or gas or vacuum) hole (with cylindrical in shape) or any other material having the lower loss-tangent than the surrounding dielectric media. Each cylinder (sphere) constitutes the cell, and hereafter mentioned the single cylinder as circular cell. Each circular cell (not shown) again can be arranged in triangular or square (not shown) way. The arrangement of the each cell here after mentioned as the lattice. According to this invention, the circular cell contains air with low dielectric constant, and is formed inside the dielectric material with higher dielectric constant. The electric field from the signal line can made to pass through
the air cell, reducing the effective dielectric constant and also reducing effective loss tangent, which results in increasing the interconnects bandwidth. Based on the parameters such as the diameter and the span etc., the electrical field distribution can be concentrated into the signal lines laid on the dielectrics system with air-holes array.

In the preferred embodiment, the circular cells with triangular and square-lattice structures are mentioned. It also includes the elliptic unit cell with square or triangular-lattice structure. In the case of the cell, the shape of circle, or square or ellipse can be used to tune the dielectric constant along with the loss tangent in the same dielectric layer. This helps to add many passive features in the interconnection such as varying the phase velocity (which is function of the dielectric constant), varying the bandwidth of the interconnect; help to adjust the skews of the signal etc. in the single interconnect system. In addition, various passive features such as the emphasis and also equalizations feature can also be made varying the dielectric constant along the path where the signal flow from transmitter to receiver.

In the preferred embodiment, the microstructure configuration with single electrode of microstrip line type is shown as signal line, the present invention also include other configurations such as strip line or coplanar type or other configuration reducing the effective dielectric constant and effective loss tangent. Single or multiple electrodes with single or multiple layers of the dielectric could also be used.

According to the preferred embodiment, ideally, the bandwidth of the electronic interconnect system can be possible to make the closer to fiber (closer to the light), if other loss due to the signal line structure such as the electrode parameter (resistance, capacitance) are neglected.

The dielectric system mentioned in the preferred embodiment also includes the photonic crystal structure (2-Dimensional and 3-Dimensional) comprising with the dielectric periodic structure and the line defect for the signal line layout. The band-gap is formed due to use of the lower dielectric material cylinder into the dielectric substrate with comparatively higher dielectric constant. In the structure, the electrical field created from the high-speed signal, flowing through the signal line (not shown) is confined and controlled in the n-plan direction by the 2D photonic band gap effect. The electrical field can be localized completely in the air-hole along the signal flowing direction making the low effective dielectric constant (low microwave loss), and thereby increasing the bandwidth of the interconnect system. By changing the shape of the cylinder for example elliptic and its different size and their span, the electrical field can be localized in the dielectric slab. This allows to have the different interconnect system having the different bandwidth by changing the dielectric constant, and signal can be made slow and high speed where it necessary. According to the preferred embodiment, the interconnect can be designed ideally having the bandwidth closer to optical fiber, and carry the high-speed electronics signal (even teraharz level). In the example, the dielectric system consisting of the 2D photonic crystal is shown. Present invention also includes the 3D photonic crystal for high-speed interconnect systems applying in the on-chip application. This also includes the means such as the connector and cable used to high-speed connection of electronic elements covering transistor to instruments.

According to the preferred embodiment, the interconnect system can be fabricated as follows; first a layer of cylindrical holes are made into a dielectric substrate. Standard IC manufacturing technology for on-chip interconnection can be used for this purpose. This is followed by the formation of the signal line. The hole can be made underneath the signal line or that portion is masked while opening the holes outside the signal line. In the preferred embodiment alternatively, the lower loss-tangent material as compared with the dielectric substrate can fill up the hole.

In the preferred embodiment, a portion of the signal line (strip lines configuration) structure is shown for explanation purpose. According to this present invention, the structure, as shown in FIGS. 5 to 11, are only made closer to the high speed signal lines, and outside of the high-speed signal lines, standard structure with uniform multilayered dielectric system can be used. This structure is for the reducing the effective dielectric constant and/or effective loss tangent of the dielectric system, which results in increasing the signal carrying capacity of the interconnects and also reduce the signal propagation delay between the channels, help to eliminate the skews between the channels. This structure help to eliminate the using of the pre-emphasize/equalization circuit and more simplify the IC design in the case of the on-chip interconnects.

According to preferred embodiment, on-chip interconnects using the dielectric system can have single or multiple techniques (for reducing the microwave loss), as explained in FIGS. 3 thru 11, open trenches or air (or gas or vacuum) hole arrays can be used in the dielectric system. Alternatively the low dielectric constant material or the liquid crystal polymer fills up the trenches or holes.

In the preferred embodiment, portions of the signal line (strip lines configuration) structure are shown for explanation purpose. This structure is for the reducing the effective dielectric constant and effective loss tangent of the dielectric system, which results in increasing the signal carrying capacity of the interconnects and also reduce the signal propagation delay between the channels, help to eliminate the skews between the channels. This structure help to eliminate the using of the repeater with or without pre-emphasize/equalization circuit and more simplify the IC design in on-chip interconnects.

In the preferred embodiments, the dielectric substrate is mentioned in an object to cover all dielectric materials, which show the dielectric properties. The dielectric materials include all kinds of ceramic materials such as Duroid, FR4, AlN, Al₂O₃, Mullite (3Al₂O₃: 2SiO₂), SiC, SiO₂, Silicon nitride, Silicon-Oxy-Nitride, BeO, Cordie-rite (magnesium alumina silicate), BN, Glass (with different compositions), epoxy glass, CaO, MnO, ZrO₂, PbO, alkali-halide (e.g. NaBr, NaCl) etc.) etc., and all kinds of the polyimides and benzocyclobutenes (BCBs) having dielectric properties. Polymer dielectric material also includes, but not limited to, Teflon, liquid crystal polymer, epoxy, parylene, silicone-polyimide, silicone-gel, and fluorinated ethylene propylene copolymer. It also includes materials of elastomers (e.g. silicone elastomer), monomers, and gels. All standard polymers can be available from the standard manufacturer for example, Du-pont, Hitachi-Chemical, Mitsui, and Mitsubishi-Chemical Industries. Gore-Tex, Japan markets liquid crystal polymer.

In the preferred embodiments as explained in FIGS. 3 to 11, dielectric systems consisting of trenches or air (vacuum or gas) holes spheres or cylinders arrays or comb-shaped with teeth into the dielectric substrate are considered. The holes, trenches or the space between the teeth in comb-shaped dielectric as shown in FIGS. 3 to 11, can be filled with air or kept vacuum, or any dielectric materials having lower dielectric constant than the dielectric substrate. Alternatively, in the preferred embodiment, holes, trenches or the space between the teeth in comb-shaped dielectric can be filled up fully by the liquid crystal material or coated by liquid crystal. The electrical field can change the orientation of the liquid crystal and can have the controllability of the effective dielectric constant and effective loss tangent of the dielectric system. The trenches shape could be the square, rectangular, circular or the shape convenient to manufacturing process.

According to the present invention, the technique of reducing the microwave-loss induced due to the dielectrics by reducing the effective loss-tangent of the dielectric system, are explained in the preferred embodiments as shown in FIGS. 3 to 11. The effective dielectric constant would also be reduced for the dielectric system of the interconnects explained as preferred embodiments, which help to reduce the signal propagation delay.

The preferred embodiments can be applied in many applications in different ways and forms. For examples, preferred embodiments mainly can be used for high speed interconnects for connecting high-speed multiple (two or more) electronics elements. The application includes, but not limited to, on-chip interconnects for example, for connecting the electronics devices and/or connection electrical and optical devices inside the IC. Different passive feature such as the pre-emphasize or equalizer can also be possible passive way utilizing the dielectric constant changes over the surface.

In the preferred embodiments as explained above, different applications are explained in an object of showing the application (of the techniques to reduce the microwave loss and increasing the bandwidth), but not limited to, the specific description provided.

In the preferred embodiments as explained in FIGS. 3 to 11, only single microstrip type or strip line configurations are considered. However, in accordance with the present invention, other signal lines, not mentioned here, such as coplanar line configuration with single or multiple signal lines (as single or differential-ended) also include. Dielectric coverage (not shown) using of the same or different dielectric material can be used. Dielectric structure consisting of trenches or multilayered of dielectric periodic structure, as shown in FIGS. 3 to 11, can also be used in the IC for high speed on-chip interconnects.

The present invention has been described above by way of its embodiments. However, those skilled in the art can reach various changes and modifications within the scope of the idea of the present invention. Therefore it is to be understood that those changes and modifications also belong to the range of this invention. For example, the present invention can be variously changed without departing from the gist of the invention, as indicated below.

According to the present invention, it is the object to provide the interconnects technique by which the microwave loss due to the dielectric, can be reduced and increased the bandwidth of the interconnects. It is also the object to use any dielectric material (including conventional dielectric material and the manufacturing technology) in the technique and could increase the bandwidth tremendously. In simplicity of drawing, preferred embodiments are described mostly considering the microstrip line configuration. However, all transmission lines configurations such as strip line, coplanar line with single or multiple signal lines (including differential line), or simple metal conductor laid on the dielectric to be used for interconnects, also cover this invention.

Several preferred embodiments for high-speed on-chip interconnects are described considering the microstrip line configuration with opened trenches or the dielectric periodic structure consisting of the cylindrical (spherical) air holes arrays. All transmission lines configurations as mentioned earlier cover under this invention. In the case of the trenches, all kinds of shapes such as the square, circular, or rectangular or any shape convenient to the manufacturing. In the case of the air-holes periodic structure, the shape of each cell could be any type such as square, or any polynomial shape, and those can be filled up by dielectric material having the lower dielectric constant than the dielectric substrate.

In the preferred embodiments as explained in FIGS. 3 to 11, in simplicity of drawings mostly surrounding of the high speed single lines are considered with having trenches opened, or air-holes periodic structure or comb-shaped dielectric structure. In on-chip interconnects, either of configurations or mixes of configuration can also be used in the multi-layered interconnects.

In the preferred embodiments as explained in FIGS. 8 and 10, for simplicity in drawing, a dielectric system comprises with the dielectric periodic structure based on the 2-D photonic (or electronics or electromagnetic) crystal is shown. The dielectric system could be based on fully photonic crystal where photonic band-gap effect can use or quasi-photonic crystal. This also includes 3D photonic (electronics or electromagnetic crystal).

In the preferred embodiments, as the open-trenches or air holes dielectric structure is used, the combination of optics and electronics interconnect are also feasible. In that case, the optical signal can pass through the trenches (air filled or kept vacuum) or opening-portion of the interconnects, speed requirement of which is over 20 Gb/s and beyond, and the electrical signal over 5 Gb/s to 40 Gb/s and beyond can flow through the metal signal lines disclosed in this invention. Additional transmission media may not be necessary to build for handling optical and electrical signal together. By doing this, high density interconnects with high signal carrying capacity can be achieved.

The advantages of this invention is that the trench of the proposed interconnects can also be used for cooling the IC. The trench can be filled with the coolant or gas to dissipate the heat generated due to electrical signal flowing through the electrical signal lines or heat generated due to the other active (e.g. transistor, amplifier etc) and passive (resistor) component's power consumption. Using this structure both cooling the IC and also high-speed performance can be achieved.

According to this invention, the interconnects with opened-trench can be used to transmit the optical signal through the air or vacuum or low loss-tangent material, filled the trench. In that case, ultra high speed interconnects comprising with electrical and optical signals can be achieved. As the same trench can be used for both electrical and optical interconnects, high density and high bandwidth interconnects can be achieved.

Although the invention has been described with respect to specific embodiment for complete and clear disclosure, the appended claims are not to be thus limited but are to be construed as embodying all modification and alternative constructions that may be occurred to one skilled in the art which fairly fall within the basic teaching here is set forth.

The present invention is expected to be found practically use in the high-speed on-chip, where the signal speed 5 Gb/s to beyond (as high as 200 Gb/s) are necessary using of the conventional material, and the bandwidth of the interconnects can be made to ideally to speed of the light for no-loss transmission line. The applications include on-chip interconnects where high-speed electronics chips or electronics chips with optical chips are need to be connected. As ideally the bandwidth of the interconnect system in IC, can be made to close to fiber, future monolithic (and also hybrid near future) integration of electronics and optical chips can also interconnected without (much or none at all) sacrificing the chips speed. The application also includes the high speed IC, or system-on-chip, 3-D IC, chip or memory interconnection, high speed parallel system for computer animation and graphics for high speed 2-D or 3-D video transmission, and high bandwidth image display, high speed router where high speed electronics switches (or IC) are needed to be interconnected.

1. An on-chip interconnection system, comprising,
(a) one or more electrical signal lines connecting a plurality of the electronics elements;
(b) a dielectric system having one or more opened trenches inside the dielectric;
(c) single (or more or none of the) ground plan, and;
(d) two or more electronics elements fabricated on the semiconductor substrate;
wherein, the said electrical signal lines on said dielectric systems forms the interconnects with the ground plan, where the opened trenches are located under or on top of the said electrical signal lines thereby reducing the microwave loss induced due to the dielectric.

2. The system according to claim 1 wherein the electrical signal line (s) have simple metal line laid on the said dielectric system, or any transmission line configuration such as microstrip line, strip line, or coplanar configuration.

3. The system according to claim 1 where in the opened trenches in the dielectric systems of the IC are used for the electrical signal lines, located in close proximity to each other.

4. The system according to claim 1 wherein the shape of the opened-trench can be one selected from the group consisting of: quadrateral, circular, square, rectangular, or any other shape convenient to the manufacturing process.

5. The system according to claim 1 wherein the single or plurality of the electrical signal line(s) with opened trenches are located in single or plurality of the layers (plans) which are aligned in parallel or perpendicular or any angle suitable to the design and manufacturing.

6. The system according to claim 1 wehere in the dielectric material removed to open the trench, is either fully removed to touch to the signal line or ground plans or partially removed, as required to achieve the interconnects performance.

7. The system according to claim 1 wherein the opened trenches are filled with the air or kept vacuum, or low dielectric material or liquid crystal dielectric material.

8. The system according to claim 1 wherein the size and shape of the opened trenches are changed along the signal lines to control the dielectric constant and also the loss-tangent of the signal lines to achieve different passive-functionality inside the IC.

9. The system as claimed in claim 1 applied to single or multiple electrical elements and/or single or multiple optical elements interconnects, wherein similar or different combination dielectric systems can be used for both electrical and optical signals transmission so that electrical signal can flow through the electrical signal line and optical signal can pass through the opened-trench made in the dielectric system.

10. The system according to claim 1 wherein the opened trench made inside the dielectric system is filled up with the coolant (gas or liquid) for cooling the IC.

11. The system according to claim 1 wherein the electrical signal lines are laid on the said dielectric system, on the side, opposite to the trench side, and the ground plan is located onto the dielectric system, separate from the said dielectric system, or the electrical signal lines are laid onto to the dielectric system, separate from the said dielectric system, and the ground plan is laid onto the side of the said dielectric system, opposite to the trench side.

12. The system according to claim 1 wherein the size and shape of the said open-trenches, are located in the same dielectrics systems or different dielectric system situated at the top of the dielectric system.

13. An on-chip interconnection system, comprising:
(a) one or more electrical signal lines connecting a plurality of the electronics elements;
(b) one or more dielectric systems, having a periodic dielectric structure in dielectric layer forming the photonics or electronics crystal;
(c) one or more ground plans, and;
(d) two or more electronics elements fabricated on the semiconductor substrate;
wherein, the photonics crystal or electronic crystal structure includes periodic structured dielectric spheres or cylinder arrays with the certain diameter and certain spans, into the bulk of dielectric material.

14. A method of fabricating an on-chip interconnection system comprising;
(a) depositing, a first dielectric layer onto a substrate;
(b) patterning and dry-etching two narrow lines having high aspect ratio (depth/space between the lines);
(c) depositing a second dielectric film leavings small trench/void in between lines;
(d) planarization, and;
(e) patterning and metallization;
wherein a metal conductor is made on the second dielectric material, the underneath of which has void or trench-openings, which reduces the microwave loss due to the dielectric.

15. A method of fabricating a periodic structure for on-chip interconnection systems comprising:
(a) depositing, a dielectric layer onto a substrate;
(b) dry etching the deposited dielectric layer to open the holes
(c) filling of the holes with polymer thereby making a pattern, and;
(d) depositing metal onto the pattern and; and
(e) lifting off excess deposited metal.

16. The system according to claim 13 wherein the crystal structure is a post formed photonic crystal or a preformed crystal such as a self assembled dielectric structure.

17. The system according to claim 13 whrein the periodic structure in said dielectric system, includes periodically structured air holes arranged surrounding the signal lines.

18. The system according to claim 13 having dielectric-periodic structures used for both optical and electrical signal transmission, wherein electrical signal is flowing through the metal line laid on the said dielectric system and the optical signal can be passed through the dielectric system either under the electrical signal line or outside, close proximity to the electrical signal line.

19. The system of claim 13 wherein a defect imparts a non-uniform characteristic of the Photonics crystal to control the optical and electrical signals independently.

20. The method according to claim 15 wherein a same mask for opening holes, via formation for the metal contact, and single dry-etching process is used for both purposes.
